(19) United States
(12) Patent Application Publication
(10) Pub. No.: US 2008/0032470 A1
(43) Pub. Date: Feb. 7, 2008

(54) METHOD FOR FABRICATING NON-VOLATILE MEMORY

(75) Inventors: Chien-Hsing Lee, Hsinchu County (TW); Tsung-Min Hsieh, Miaoli County (TW); Jhyy-Cheng Liou, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: SOLID STATE SYSTEM CO., LTD., Hsinchu (TW)

(21) Appl. No.: 11/462,372

(22) Filed: Aug. 4, 2006

(51) Int. Cl. H01L 21/8244

(52) U.S. Cl. 438/238

(57) ABSTRACT

A method for fabricating non-volatile memory on a substrate includes forming a plurality of doped lines in the substrate along a first direction, wherein the doped lines serve as a plurality of bit lines, and portions of each of the doped lines serves as source/drain regions for a plurality of memory cells. A charge storage stacked layer is formed over the substrate, wherein the charge storage stacked layer includes a charge trapping layer. A conductive layer is formed over the charge storage layer. The conductive layer and the charge storage stacked layer are patterned to form a plurality of word lines along a second direction, intersecting with the first directing. The remaining portion of the charge trapping layer is just under the word lines, not covering the isolation region between the word lines.

### BACKGROUND OF THE INVENTION

1. Field of Invention

The invention relates to a method for fabricating non-volatile memory. More particularly, the invention relates to a method for fabricating non-volatile memory with improved isolation function, so as to reduce leakage current.

2. Description of Related Art

Non-volatile memory, such as a flash memory, is very common for storing a binary data. Particularly, the (silicon oxide nitride oxide silicon) SONOS type memory has the nitride layer for trapping the charges. The trapped charges in the charge trapping layer would change the threshold of the memory cell. The binary data can be determined according to the threshold voltage.

In other words, the charge trapping layer is the essential layer in storing the binary data. The non-volatile memory usually includes a number of memory cells, arranged in 2-dimensional cell array. FIG. 1 is a top view, schematically illustrating a layout of an array of non-volatile memory. In FIG. 1, only three bit lines BL0-BL2 and three word lines WL0-WL2 in the memory region of a substrate are shown as the example. FIG. 2 is a cross-sectional view, schematically illustrating a conventional structure of the memory cell along the cross-section direction X1 in FIG. 1.

In FIG. 1 and FIG. 2, only taking the bit lines BL0 and BL1 as the example for descriptions, the bit lines 102 are the doped lines in the substrate 100 along a direction. An oxide/nitride/oxide (ONO) layer 104 is formed on the substrate 100. A plurality of world lines 106, such as polysilicon lines, is formed over the substrate 100 along another direction. A portion of the word line 106 between two bit lines 102 also serves as the gate electrode of the memory cell. The world lines 106 intersect with the bit lines 102. The intersection portions between the world lines 106 and the bit lines 102 serve as the source/drain region.

FIG. 3 is a cross-sectional view, schematically illustrating the conventional structure of the memory cell along the cross-section direction X2 in FIG. 1. In FIG. 1 and FIG. 3, in order to reduce the memory size and the fabrication processes, the portion of the substrate between the memory cells belonging to different word lines also serves as the isolation, including the dotted region in FIG. 1. In FIG. 3, there is no word line remaining. However, in the conventional fabrication process, the ONO layer 104 still remains on the substrate 100.

In this kind of memory cell, the nitride layer in the ONO layer 104 is used to trap the charges, so as to store a binary data depending on whether or not the charges are trapped in the nitride layer of the ONO layer 104 under the gate electrode region. However, during fabrication process, some electro static charges 108 may be trapped in the nitride layer at the isolation region. In addition, the accessing operation of the memory cell may also cause residual charges 108 in the nitride layer within the isolation region. When the amount of the residual charges 108, such as the residual positive charges, is greater than a certain level, this residual charges may affect the memory cell and, for example, cause a leakage current between the bit lines within the isolation region. It should be noted that there are many cells controlled by one bit line. Although each cell may just cause a small leakage current, the accumulation of leakage current in the whole bit line may be sufficient large, resulting in error for accessing the binary data of the accessed cell.

The foregoing similar accessing error also occurs in another cell structure. FIG. 4 is a top view, schematically illustrating a layout of an array of another non-volatile memory. In FIG. 4, only three bit lines BL0-BL2 and three word lines WL0-WL2 in the memory region of a substrate are shown as the example. In addition, several selection gates SG0, SG1 . . . are formed between the bit lines. The isolation regions 110, as a portion of substrate, are indicated by the dotted area. A portion of the bit lines also serves as source/drain regions of the memory cells.

FIG. 5 is a cross-sectional view, schematically illustrating a conventional structure of the memory cell along the cross-section direction X3 in FIG. 4. In FIG. 4 and FIG. 5, the bit lines 152 are formed form the doped lines in the substrate 150 along a direction. The stacked selection gate lines are formed between the bit lines 152. Each of the stacked selection gate lines includes a gate oxide layer 154, a selection gate layer 156, and a cap layer 157. Then, an ONO layer 158 is formed over the substrate 150, including covering the sidewalls and top surface of the stacked selection gate lines. Then a polysilicon layer is formed over the substrate 150 and is patterned into several word lines 160. The word lines 160 are intersecting with the bit lines 152. A portion of the nitride layer in the ONO layer 158 between the bit line and the selection gate line 156 on the substrate 150 is used to store the charges in recording the binary data. When the selection gate layer 156 is applied with an operation voltage, the substrate under the selection gate layer 156 is converted into a conducting region to pass the operation voltage and therefore serve as another source/drain region. Further, a portion of the word line 160 above the charge storage region between the bit line and the stacked selection gate line serves as the gate electrode. The operation mechanism should be understood by the person with ordinary skill and is not further described.

FIG. 6 is a cross-sectional view, schematically illustrating the conventional structure of the memory cell along the cross-section direction X4 in FIG. 4. In FIG. 4 and FIG. 6, a portion of the substrate between the memory cells belonging to different word lines also serves as the isolation region 110, including the dotted region in FIG. 4. In FIG. 6, there is no word line remaining. However, in the conventional fabrication process, a portion of the ONO layer 158a still remain on the substrate 150 between the word lines 160, including the nitride layer, in which the isolation region 110 is still covered by the ONO layer 158a. With the similar phenomenon in FIG. 3, the residual charges 162 may be trapped in the nitride layer of the ONO layer 158s. The residual charges 162 may cause the leakage current, resulting in access error on the binary data of the memory cells.

In the conventional fabrication, the nitride layer still remains above the isolation region. According to the investigation of the invention, the leakage current may occur, causing access error. The conventional fabrication process does not at least specifically consider the issues described above.

### SUMMARY OF THE INVENTION

The invention provides a fabrication method for a non-volatile memory. The isolation region between the word lines is not covered by a charge trapping layer. As a result, the leakage current can be reduced, and the accessing error can therefore be reduced.

The invention provides a method for fabricating non-volatile memory on a substrate. The method includes forming a plurality of doped lines in the substrate along a first direction. Wherein, the doped lines serve as a plurality of bit lines, and portions of each of the doped lines serve as source/drain regions for a plurality of cmemory cells. A charge storage stacked layer is formed over the substrate, wherein the charge storage stacked layer comprises a charge trapping layer. A conductive layer is formed over the charge storage layer. A mask layer is formed over the conductive layer, wherein the mask layer has a plurality of mask lines along a second direction, intersecting with the first direction. A first etching process is performed on the conductive layer with the mask layer, to form a plurality of word lines, wherein portions of each of the word lines between the bit lines serve as gate electrodes for the memory cells. A second etching process is performed on the charge storage stacked layer with the mask layer, to remove at least a portion of the charge trapping layer not being covered by the mask layer. The mask layer is then removed.

The invention also provides alternative method for fabricating a non-volatile memory on a substrate. The method includes forming a plurality of doped lines in the substrate along a first direction, wherein the doped lines serve as a plurality of bit lines, and portions of each of the doped lines serve as source/drain regions for a plurality of memory cells. A plurality of stacked selection gate lines is formed along the first direction between the bit lines. A charge storage stacked layer is formed over the substrate, wherein the charge storage stacked layer comprises a charge trapping layer. A conductive layer is formed over the charge storage layer. A mask layer is formed over the conductive layer, wherein the mask layer has a plurality of mask lines along a second direction. A first etching process is performed on the conductive layer with the mask layer, to form a plurality of word lines. A second etching process is performed on the charge storage stacked layer with the mask layer, to remove at least a portion of the charge trapping layer not being covered by the mask layer. As a result, a remaining portion of the charge storage stacked layer on sidewalls of the stacked selection gate lines form spacers. Portions of each of the word lines between the bit lines and the stacked selection gate lines serve as gate electrodes for the memory cells. The mask layer is removed.

The invention provides a method for fabricating non-volatile memory on a substrate includes forming a plurality of doped lines in the substrate along a first direction, wherein the doped lines serve as a plurality of bit lines, and portions of each of the doped lines serve as source/drain regions for a plurality of memory cells. A charge storage stacked layer is formed over the substrate, wherein the charge storage stacked layer includes a charge trapping layer. A conductive layer is formed over the charge storage layer. The conductive layer and the charge storage stacked layer are patterned to form a plurality of word lines along a second direction, intersecting with the first directing. The remaining portion of the charge trapping layer is under the word lines, not covering the isolation region between the word lines.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view, schematically illustrating a layout of an array of non-volatile memory.

FIG. 2 is a cross-sectional view, schematically illustrating a conventional structure of the memory cell along the cross-section direction X1 in FIG. 1.

FIG. 3 is a cross-sectional view, schematically illustrating the conventional structure of the memory cell along the cross-section direction X2 in FIG. 1.

FIG. 4 is a top view, schematically illustrating a layout of an array of another non-volatile memory.

FIG. 5 is a cross-sectional view, schematically illustrating a conventional structure of the memory cell along the cross-section direction X3 in FIG. 4.

FIG. 6 is a cross-sectional view, schematically illustrating the conventional structure of the memory cell along the cross-section direction X4 in FIG. 4.

FIGS. 7A-7D are cross-sectional views, schematically illustrating the processes for forming a non-volatile memory, according to an embodiment of the invention.

FIGS. 8A-8D are cross-sectional views, schematically illustrating the processes for forming a non-volatile memory, according to another embodiment of the invention.

### DESCRIPTION OF THE PREFERRED EMBODIMENTS

In the invention, a novel non-volatile memory is proposed, so that the leakage current from the isolation region between the word lines can be effectively reduced, and the accessing error can be therefore reduced. Several embodiments are provided for description of the invention. However, the invention is not just limited to the embodiments.

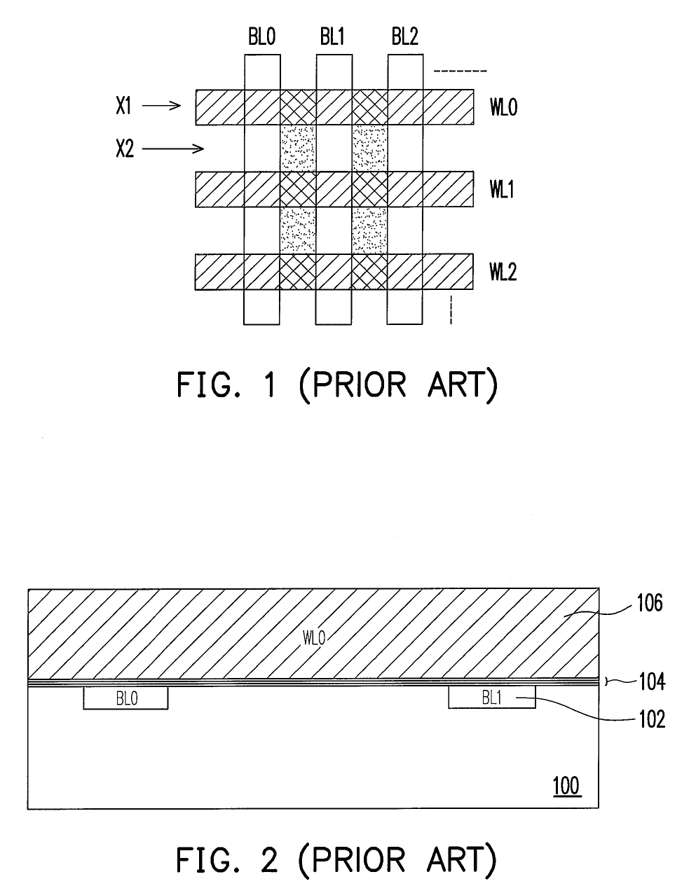

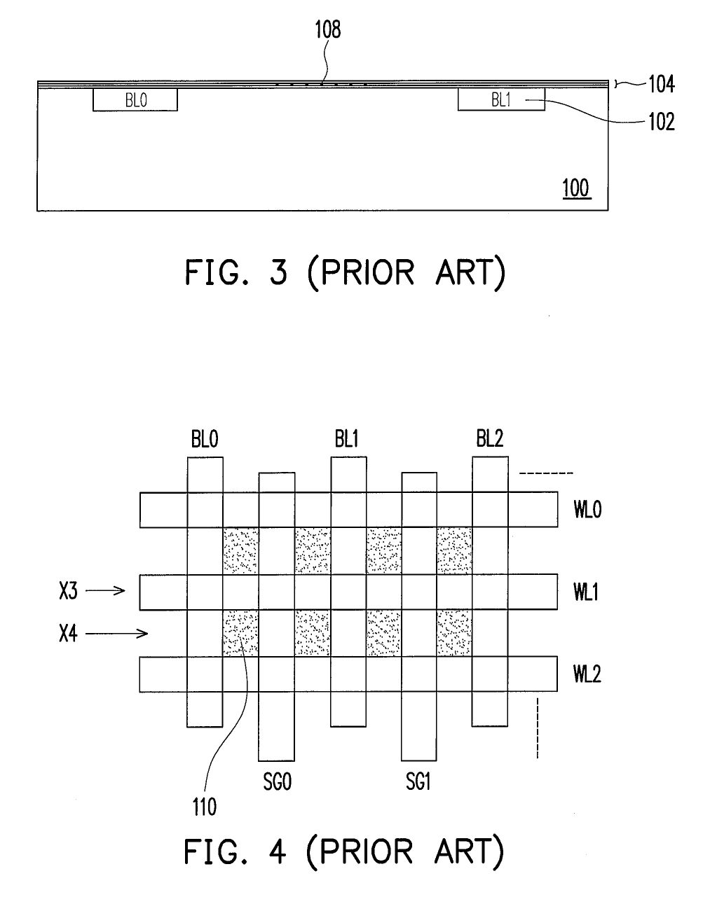

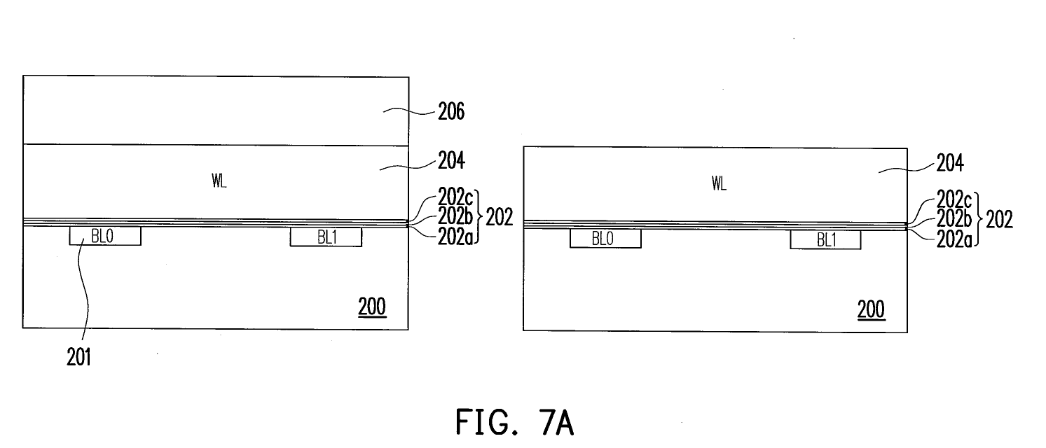

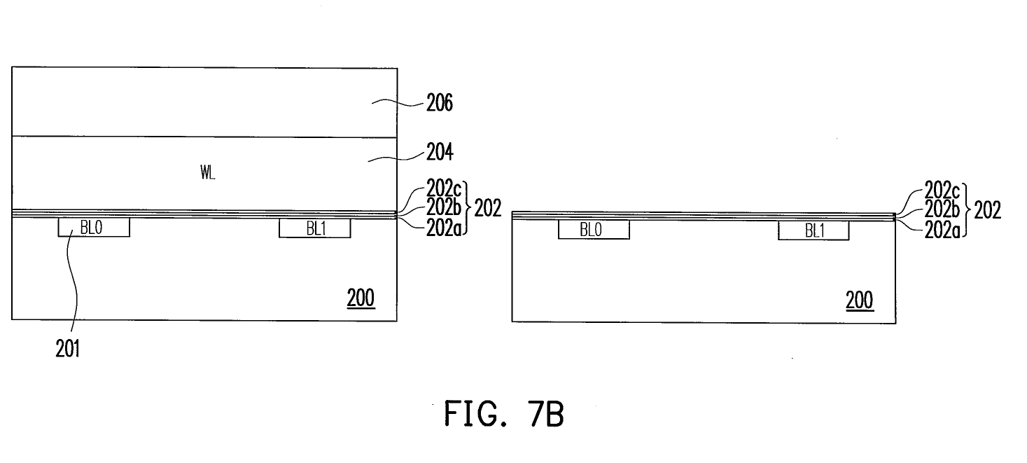

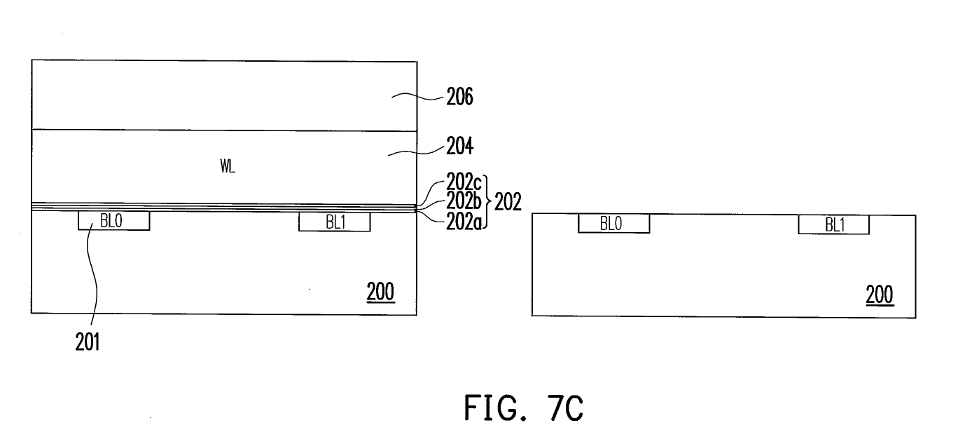

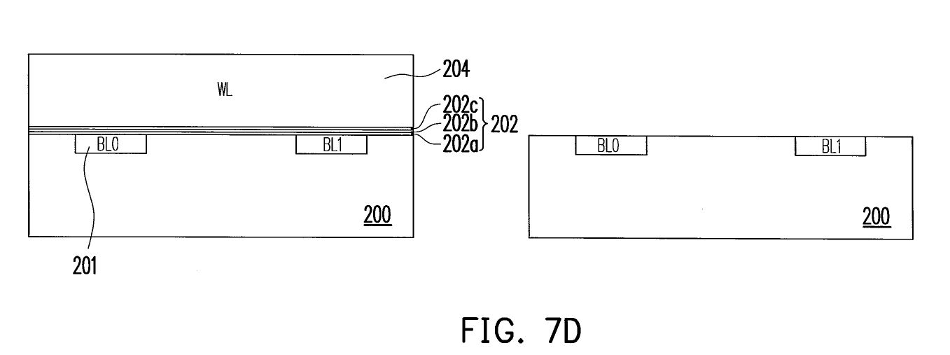

FIGS. 7A-7D are cross-sectional views, schematically illustrating the processes for forming a non-volatile memory, according to an embodiment of the invention. The layout of the non-volatile memory is similar to the layout in FIG. 1. However, due to the fabrication method of the present invention, the charge trapping layer is significantly removed at the isolation region, according to the investigation of leakage current by the invention. In FIGS. 7A-7D, the left cross-section views are along the cross-section direction X1 in FIG. 1, and the right cross-section views are along the cross-section direction X2 in FIG. 1.

In FIG. 7A, a substrate 200 is provided. Then, multiple bit lines 201 are formed in the substrate 200 at the memory area. Here, the fabrication at the peripheral area is not described. The bit lines 201 can be the doped lines in the substrate along a first direction. In addition, portions of each of the bit lines 201 serve as source/drain regions for a plurality of memory cells. A charge storage stacked layer 202 is formed over the substrate. The charge storage stacked layer 202 comprises a charge trapping layer 202b. In the usual structure, the charge storage stacked layer 202 include, for example, a bottom oxide layer 202a, a charge trapping layer 202b, and a top oxide layer 202c. The charge trapping layer 202b is, for example, nitride layer, Si rich silicon nitride layer (i.e SiN), tantalum oxide layer (i.e. Ta₂O₅), aluminum oxide layer (i.e. Al₂O₃) or nano-crystal silicon layer. In general, any kind of material capable of trapping charge can be used.

A conductive layer 204 is formed over the charge storage layer 202. The conductive layer 204 can be, for example, polysilicon layer, and can be formed by, for example, chemical vapor deposition (CVD). Then, a mask layer 206 is formed on the conductive layer 204. The mask layer 206 can be, for example, a photoresist layer with a pattern, correspond to the word lines (WL). In other words, the mask layer 206 is not at the cross-section direction X2 at the right drawing. The pattern of mask layer 206 includes multiple lines along another direction, intersecting with the bit lines 201.

In FIG. 7B, a first etching process is performed on the conductive layer 204 with the mask layer 206, so as to form a plurality of word lines (WL), which is a remaining portion of the conductive layer 204 at the cross-section direction X1 (see left drawing) but not at the cross-section direction X2 (see right drawing). It should be noted that portions of each of the word lines (WL) 204 between the bit lines 201 serve as gate electrodes for the memory cells. Since the conductive layer 204, such as the polysilicon, has the different etching ratio to the dielectric layer of the charge storage stacked layer 202 with the top oxide dielectric layer 202c, the first etching process may stop on the top oxide dielectric layer 202c.

A second etching process is further needed to etch the charge storage stacked layer 202 at the portion not covered by the mask layer 206. Remarkably, in general, at least a portion of the charge trapping layer 202b not being covered by the mask layer 206 is removed. In other words, the bottom oxide layer 202a may still remain on the substrate 200. However, for the easy process, a proper etchant can be used to etch the oxide and nitride but not the silicon, so that the second etching can remove the charge storage stacked layer 202 without etching the substrate 200. In FIG. 7D, after removing the mask layer 206, the remaining portion of the conductive layer 204 has several word lines at the cross-section direction X1 but not at the cross-section direction X2. In this kind of non-volatile memory, a portion of the substrate 200 between the word lines and between the bit lines also serve as the isolation region. The isolation region is not covered by the charge trapping layer 202b. Alternatively, the region between the word lines has no the charge trapping layer 202b.

However, if the exposed portion of the substrate 200 between the word lines is necessary to be further protected, such as the situation shown in FIG. 7D, another protection oxide layer (not shown) can be optionally formed on the substrate 200 by, for example, thermal oxidation process. The protection oxide layer may also improve the isolation function.

In the invention as shown in FIG. 7D, there is no charge trapping layer existing the substrate 200 at the cross-section direction X2. The residual charges do not exit too. Therefore, the conventional leakage current for the non-volatile memory with doped bit lines in the substrate can be significantly reduced.

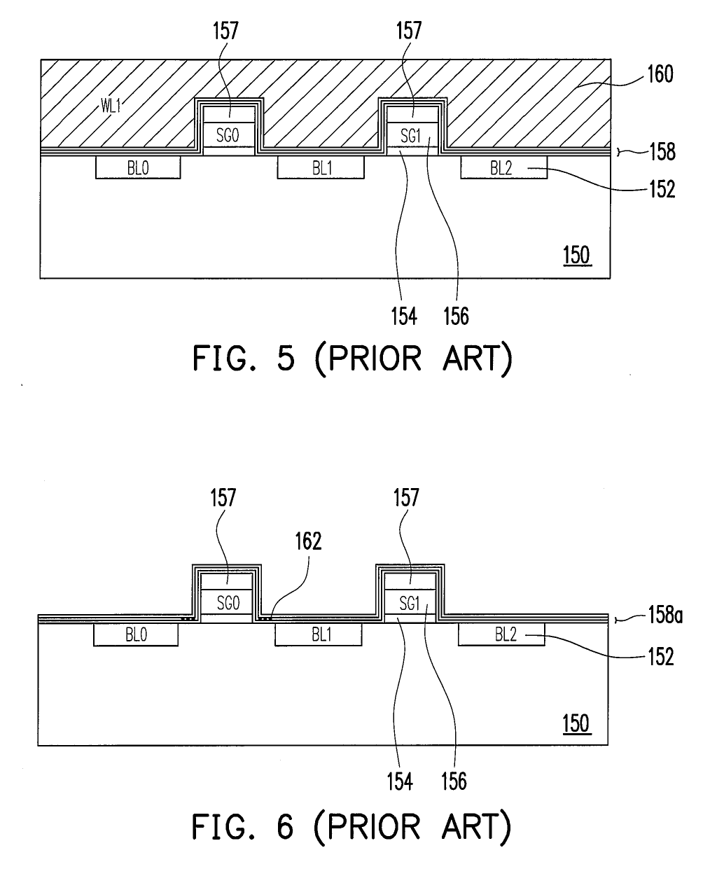

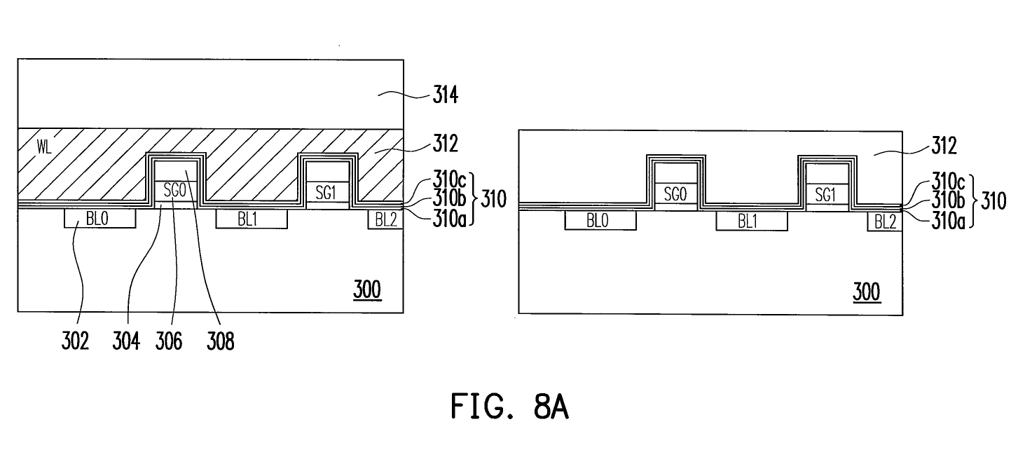

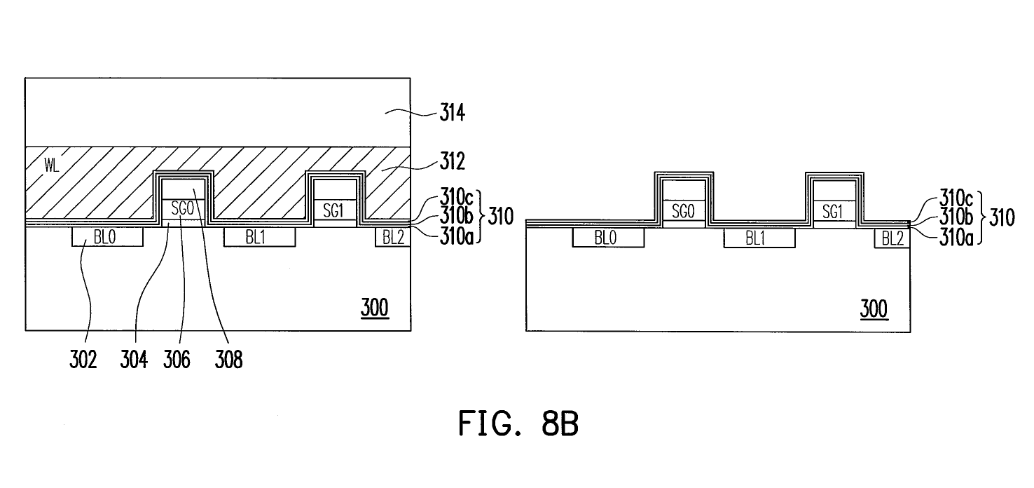

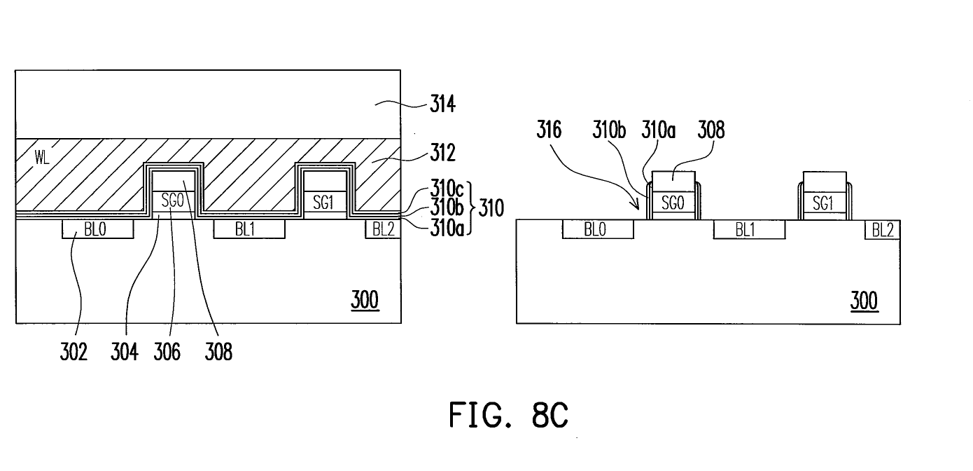

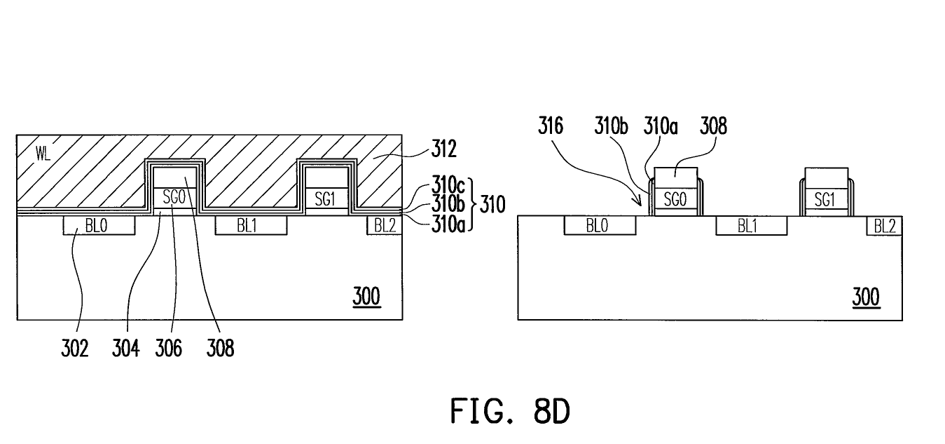

Remarkably, the features of the invention can also be apply to another design of non-volatile memory. For example, FIGS. 8A-8D are cross-sectional views, schematically illustrating the processes for forming a non-volatile memory, according to another embodiment of the invention. The processes in FIGS. 8A-8D are for forming the non-volatile memory based on the layout in FIG. 4. The non-volatile memory also includes the selection gate. However, the consideration on leakage current is the same as that in the layout of FIG. 1. The left drawings in FIGS. 8A-8D are along the cross-section direction X3 in FIG. 4 and the right drawings are along the cross-section direction X4 in FIG. 4.

In FIG. 8A, a substrate 300 is provided. A plurality of doped lines 302 is formed in the substrate along a first direction at the memory region. The doped lines 302 also serve as a plurality of bit lines 302 (BL0, BL1, BL1, . . . ). Portions of each of the doped lines 302 serve as source/drain regions for a plurality of memory cells. A plurality of stacked selection gate lines (SG0, SG1, . . . ), including the gate dielectric layer 304, the selection gate layer 306 and the cap layer 308, is formed on the substrate 300 along a first direction between the bit lines 302. The stacked selection gate lines can be formed by, for example, sequentially depositing a gate oxide layer, a polysilicon layer, and a cap layer, such as a nitride cap layer, over the substrate 300, and then the three layers are patterned by photolithographic and etching process into the gate dielectric layer 304, the selection gate layer 306 and the cap layer 308, between the bit lines 302. Here, the cap layer 308 is used to further improve the isolation the selection gate layer 306 from the word lines (WL) 312 because the ONO layer 310 is too thin.

Then, a charge storage stacked layer 310 is formed over the substrate 300, wherein the charge storage stacked layer 310 comprises, for example, a bottom oxide layer 310a, a charge trapping layer 310b, and a top oxide layer 310c. The charge storage stacked layer 310 also cover the sidewall an top surface of the stacked selection gate lines (SG0, SG1, . . . ). A conductive layer 312, such as a polysilicon layer, is formed over the substrate 300 on the charge storage stacked layer 310. The conductive layer 312 is to be patterned into the word lines (WL). For example, a mask layer 314 is formed over the conductive layer 312. The mask layer 314 is, for example, a photoresist layer with a pattern having multiple lines along another direction intersecting with the bit lines 302.

The mask layer 314 is used as the etching mask, and the etching process is performed to remove a portion of the conductive layer 312, not covered by the mask layer 314. As a result, the portion of the conductive layer at the cross-section direction X4 (right drawing) is removed to expose the charge storage stacked layer 310, while the portion of the conductive layer 312 at the cross-section direction X3 (left drawing) remains.

An etching back process is performed with the same mask layer 314, so that the exposed portion of the charge storage stacked layer 310 is removed. As a result, a spacer is formed on the sidewall of the stacked selection gate lines formed from the gate dielectric layer 304, the selection gate layer 306 and the cap layer 308. The spacer is the remaining portion of the charge storage stacked layer 310 due to the etching back process, as well known by the person with ordinary skill. Here, the spacer is, for example, shown with the remaining portion of the charge trapping 310b and the bottom oxide layer 310a. However, the remaining portion of the top oxide layer 310c is small portion and is not shown here. The spacer is naturally formed due to the etching back process as well known in conventional skill. Next in FIG. 8D, the mask layer 314 is removed. It should be also noted that the charge trapping layer 310b is significantly removed. However, another oxide layer may be optionally further formed to protect the exposed portion of the substrate 300.

The essential features to be noted here are that the charge trapping layer 310b at the cross-section direction X4 between the word lines WL is substantially removed except the portion in the spacer. Therefore, there is not charge trapping layer in the region 316. This can significantly reduce the accumulation of residual charges, and the therefore reduce the leakage current. The accessing error of the data is then reduced.

As can be seen from the foregoing embodiments, the invention has looked into the leakage current in the conventional fabrication process for the non-volatile memory with the bit line, doped in the substrate. The leakage current can be solved by the invention for these specific types of non-volatile memory. Since the leakage current can be significantly reduced, the accessing error is reduced, accordingly.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method for fabricating non-volatile memory on a substrate, comprising:
forming a plurality of doped lines in the substrate along a first direction, wherein the doped lines serve as a plurality of bit lines, and portions of each of the doped lines serve as source/drain regions for a plurality of memory cells;
forming a charge storage stacked layer over the substrate, wherein the charge storage stacked layer comprises a charge trapping layer;
forming a conductive layer over the charge storage layer;
forming a mask layer over the conductive layer, wherein the mask layer has a plurality of mask lines along a second direction, intersecting with the first direction;
performing a first etching process on the conductive layer with the mask layer, to form a plurality of word lines, wherein portions of each of the word lines between the bit lines serve as gate electrodes for the memory cells;
performing a second etching process on the charge storage stacked layer with the mask layer, to remove at least a portion of the charge trapping layer not being covered by the mask layer; and
removing the mask layer.

2. The method of claim 1, wherein the charge storage stacked layer comprises a bottom oxide layer, the charge trapping layer, and a top oxide layer.

3. The method of claim 2, wherein the charge trapping layer is a nitride layer.

4. The method of claim 2, wherein in the step of performing the second etching process, the bottom oxide remains over the substrate.

5. The method of claim 1, wherein a material for the charge trapping layer in the charge storage stacked layer comprises nitride, Si-rich silicon nitride, tantalum oxide, aluminum oxide, or nano-crystal silicon.

6. The method of claim 1, wherein after the step of performing the second etching process, an oxide layer is further formed over the substrate between the word lines.

7. The method of claim 1, wherein in the step of performing the second etching process, a portion of the substrate between the word lines is exposed.

8. A method for fabricating non-volatile memory on a substrate, comprising:
forming a plurality of doped lines in the substrate along a first direction, wherein the doped lines serve as a plurality of bit lines, and portions of each of the doped lines serve as source/drain regions for a plurality of memory cells;
forming a plurality of stacked selection gate lines along the first direction between the bit lines;
forming a charge storage stacked layer over the substrate, wherein the charge storage stacked layer comprises a charge trapping layer;
forming a conductive layer over the charge storage layer;
forming a mask layer over the conductive layer, wherein the mask layer has a plurality of mask lines along a second direction;
performing a first etching process on the conductive layer with the mask layer, to form a plurality of word lines;
performing a second etching process on the charge storage stacked layer with the mask layer, to remove at least a portion of the charge trapping layer not being covered by the mask layer, wherein a remaining portion of the charge storage stacked layer on sidewalls of the stacked selection gate lines form spacers, wherein portions of each of the word lines between the bit lines and the stacked selection gate lines serve as gate electrodes for the memory cells; and
removing the mask layer.

9. The method of claim 8, wherein the charge storage stacked layer comprises a bottom oxide layer, the charge trapping layer, and a top oxide layer.

10. The method of claim 9, wherein a material of the charge trapping layer comprises nitride, Si-rich silicon nitride, tantalum oxide, aluminum oxide, or nano-crystal silicon.

11. The method of claim 9, wherein in the step of performing the second etching process, the bottom oxide remains over the substrate.

12. The method of claim 8, wherein the charge trapping layer in the charge storage stacked layer comprises a nitride layer.

13. The method of claim 8, wherein after the step of performing the second etching process, an oxide layer is further formed over the substrate between the word lines.

14. The method of claim 8, wherein in the step of performing the second etching process, a portion of the substrate between the word lines is exposed.

15. The method of claim 8, wherein the step of forming the stacked selection gate lines comprises forming a gate dielectric line, a selection gate line, and a cap line stacked in each of the stacked selection gate lines.

16. The method of claim 15, wherein the cap layer is a nitride cap layer for isolating the selection gate lines from the word lines.

17. A method for fabricating non-volatile memory on a substrate, comprising:
forming a plurality of doped lines in the substrate along a first direction, wherein the doped lines serve as a plurality of bit lines, and portions of each of the doped lines serve as source/drain regions for a plurality of memory cells;
forming a charge storage stacked layer over the substrate, wherein the charge storage stacked layer comprises a charge trapping layer;
forming a conductive layer over the charge storage layer; and
patterning the conductive layer and the charge storage stacked layer to form a plurality of word lines along a second direction, intersecting with the first direction,
wherein the patterned charge trapping layer does not cover an isolation region, and the isolation region is a region of the substrate between the word lines.

18. The method of claim 17, wherein before the step of forming the charge storage stacked layer, further comprising forming a stacked selection gate lines along the first direction between the bit lines.

19. The method of claim 17, wherein the charge storage stacked layer comprises a bottom oxide layer, the charge trapping layer, and a top oxide layer.

20. The method of claim 17, wherein a material of the charge trapping layer in the charge storage stacked layer comprises nitride, Si-rich silicon nitride, tantalum oxide, aluminum oxide, or nano-crystal silicon.
